(19) United States
(12) Patent Application Publication
(10) Pub. No.: US 2018/0122968 A1
(43) Pub. Date: May 3, 2018

(54) FINGER ELECTRODE FOR SOLAR CELL AND METHOD OF MANUFACTURING THE SAME

(71) Applicant: SAMSUNG SDI CO., LTD., Yongin-si (KR)

(72) Inventors: Dae Sub SONG, Suwon-si (KR); Jae Hwi CHO, Suwon-si (KR)

(21) Appl. No.: 15/632,452

(22) Filed: Jun. 26, 2017

(30) Foreign Application Priority Data
Oct. 28, 2016 (KR) 10-2016-0142437

(51) Int. Cl. H01L 31/0224

(52) U.S. Cl. CPC H01L 31/022433

(57) ABSTRACT

A finger electrode for a solar cell formed using a conductive paste comprising a conductive powder, a glass frit, and an organic vehicle. A linewidth A′ of the finger electrode at a point 0.5H satisfies the following Equation 1: 0.5A≤A′≤0.75A where H is the height of the finger electrode and A is the linewidth of a base of the finger electrode.

### CROSS-REFERENCE TO RELATED APPLICATION

Korean Patent Application No. 10-2016-0142437, filed on Oct. 28, 2016, in the Korean Intellectual Property Office, and entitled: “Finger Electrode for Solar Cell and Method of Manufacturing the Same,” is incorporated by reference herein in its entirety.

### BACKGROUND

### 1. Field

Embodiments relate to a finger electrode for a solar cell and a method of manufacturing the same.

### 2. Description of the Related Art

Solar cells generate electricity using the photovoltaic effect of a p-n junction which converts photons of sunlight into electricity. In the solar cell, front and rear electrodes are respectively formed on upper and lower surfaces of a semiconductor wafer or substrate with the p-n junction therebetween. Then, the photovoltaic effect at the p-n junction is induced by sunlight entering the semiconductor wafer and electrons generated by the photovoltaic effect at the p-n junction provide electric current through the electrodes.

Such a solar cell electrode is generally manufactured by placing a printing mask having openings for formation of electrodes on a semiconductor substrate, placing a conductive paste on the printing mask, and printing the conductive paste on the semiconductor substrate through the openings of the printing mask in the form of electrodes, followed by baking the printed conductive paste.

FIG. 1 shows an image of a general printing mask used in formation of a solar cell electrode. Referring to FIG. 1, such a general printing mask is manufactured by applying a photosensitive resin 14 to a mesh 12 arranged obliquely with respect to the longitudinal direction of the printing mask and selectively removing a portion of the photosensitive resin at which an electrode will be printed using a photoresist process, thereby forming an electrode printing portion 16. Such a general printing mask for formation of solar cell electrodes has an opening rate of 45% to 60%, wherein the opening rate refers to the proportion of the area occupied by a mesh-free portion to the total area of the electrode printing portion.

### SUMMARY

Embodiments are directed to a finger electrode for a solar cell formed using a conductive paste comprising a conductive powder, a glass frit, and an organic vehicle. A linewidth N of the finger electrode at a point 0.5H satisfies the following Equation 1: 0.5A≤A′≤0.75A where H is the height of the finger electrode and A is the linewidth of a base of the finger electrode.

The linewidth A of the base of the finger electrode may range from about 30 μm to about 100 μm.

The height H of the finger electrode may range from about 10 μm to about 20 μm.

The conductive paste may include about 60 wt % to about 95 wt % of the conductive powder, about 0.5 wt % to about 20 wt % of the glass frit, and about 1 wt % to about 30 wt % of the organic vehicle.

The glass fit may include at least one of a bismuth-tellurium-oxide (Bi—Te—O)-based glass fit, a lead-tellurium-oxide (Pb—Te—O)-based glass frit, and a lead-bismuth-tellurium-oxide (Pb—Bi—Te—O)-based glass frit.

The conductive paste may further include at least one additive selected from a dispersant, a thixotropic agent, a plasticizer, a viscosity stabilizer, an anti-foaming agent, a pigment, a UV stabilizer, an antioxidant, and a coupling agent.

Embodiments are also directed to a method of manufacturing a finger electrode for a solar cell. The method includes printing a conductive paste on a front surface of a substrate using a printing mask having an opening rate of about 65% or more, and baking the printed conductive paste.

The printing mask may have an opening rate of about 65% to about 90%.

The printing mask may include a mesh, a photosensitive resin layer integrated with the mesh, and an electrode printing portion formed by removing the photosensitive resin layer.

The mesh may include weft threads. A distance between weft threads of the mesh above and below the electrode printing portion may be longer than the distance between weft threads of the mesh in other regions of the printing mask.

Baking of the conductive paste may be performed at about 600° C. to about 1,000° C.

### BRIEF DESCRIPTION OF DRAWINGS

Features will become apparent to those of skill in the art by describing in detail exemplary embodiments with reference to the attached drawings in which:

FIG. 1 illustrates a view of a general printing mask used in formation of a finger electrode for a solar cell.

FIG. 2 illustrates a view of a printing mask having a high opening rate according to embodiments.

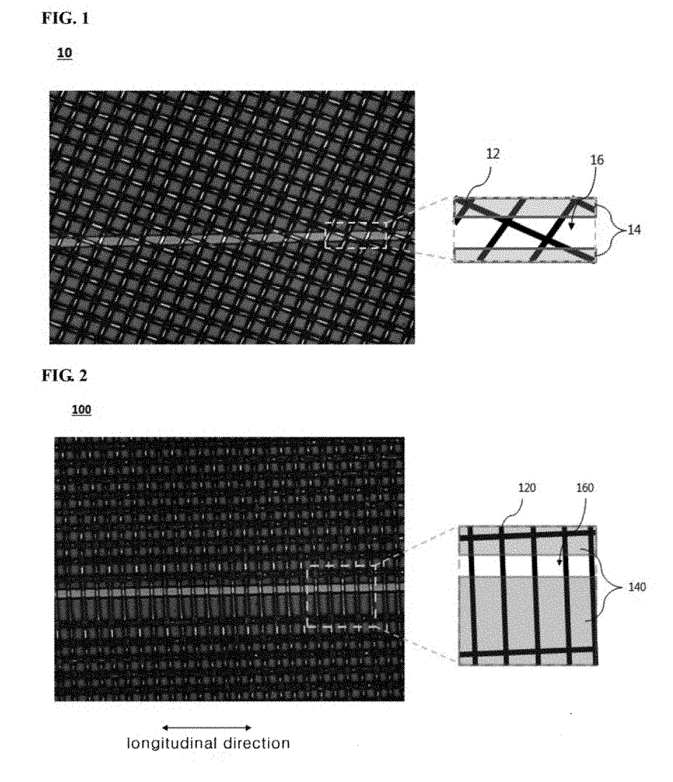

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration.

Hereinafter, embodiments will be described in detail.

After extensive research to develop a finger electrode for a solar cell exhibiting a small height-dependent reduction in linewidth, the present inventors found that it is possible to fabricate a finger electrode for a solar cell exhibiting a small height-dependent reduction in linewidth using a printing mask having an opening rate of about 65% or more.

First, a method of manufacturing a finger electrode for a solar cell will be described.

The method of manufacturing a finger electrode for a solar cell includes: (a) printing a conductive paste on a front surface of a substrate using a printing mask having an opening rate of about 65% or more; and (b) baking the printed conductive paste.

Next, the printing mask will be described.

FIG. 2 illustrates an example of the printing mask 100 according to embodiments. Referring to FIG. 2, the printing mask 100 may include a mesh 120, a photosensitive resin layer 140 integrated with the mesh 120, and an electrode printing portion 160 formed by removing the photosensitive resin layer. The printing mask 100 may have an opening rate of about 65% or more, or, for example, about 65% to about 90%. For example, the printing mask 100 has an opening rate of about 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, or 90%. The opening rate is calculated according to Equation 2:

Opening rate (%)={(Area of electrode printing portion−Area occupied by mesh in electrode printing portion)/Area of electrode printing portion}×100. [Equation 2]

When the finger electrode is formed using the printing mask 100 including the electrode printing portion having the high opening rate, the amount of conductive paste printed on the substrate may be increased for a given area such that reduction in linewidth of the electrode can be minimized, thereby increasing the total electrode area. As a result, short-circuit current is increased and serial resistance is reduced, thereby realizing high conversion efficiency.

In the printing mask 100, warp threads of the mesh may be at an angle of about 80° to about 105°, or, for example, about 85° to about 105° with respect to the longitudinal direction of the printing mask. When the angle of the warp threads of the mesh falls within the above range, the area occupied by the mesh 120 in the electrode printing portion 160 may be minimized, thereby obtaining a high opening rate. For example, warp threads of the mesh may be at an angle of about 80°, 81°, 82°, 83°, 84°, 85°, 86°, 87°, 88°, 89°, 90°, 91°, 92°, 93°, 94°, 95°, 96°, 97°, 98°, 99°, 100°, 101°, 102°, 103°, 104° or 105° with respect to the longitudinal direction of the printing mask 100.

In addition, as shown in FIG. 2, the distance between weft threads of the mesh 120 above and below the electrode printing portion 160 may be longer than the distance between weft threads of the mesh 120 in other regions of the printing mask 100. Herein, the ten is “above” and “below” may be understood with reference to FIG. 2, wherein “above” refers to a location between the electrode printing portion 100 and the top of the drawing, and “below” refers to a location between the electrode printing portion 100 and a bottom of the drawing. When the distance between the weft threads of the mesh 120 adjacent the electrode printing portion 160 is relatively long, the area occupied by the mesh 120 in the electrode printing portion 160 may be minimized while preventing reduction in printability that could be caused by tension that may be applied to the printing mask by a pressing device during printing of the conductive paste.

The substrate may be a substrate having a p-n junction formed thereon. For example, the substrate may include a semiconductor substrate and an emitter. The substrate may be prepared for example, by doping one surface of a p-type semiconductor substrate with an n-type dopant to form an n-type emitter. In some implementations, the substrate may be prepared by doping one surface of an n-type semiconductor substrate with a p-type dopant to form a p-type emitter.

The semiconductor substrate may be formed of crystalline silicon or a compound semiconductor. The crystalline silicon may be monocrystalline or polycrystalline. For example, the semiconductor substrate may be a silicon wafer.

The p-type dopant may be a material including a group III element such as boron, aluminum, or gallium. The n-type dopant may be a material including a group V element, such as phosphorus, arsenic or antimony.

Next, the conductive paste will be described. The conductive paste may include a conductive powder, a glass frit, and an organic vehicle.

(1) Conductive Powder

The conductive powder may be or include a suitable conductive powder generally used in solar cell electrodes, such as silver, aluminum, nickel, copper, or a combination thereof. For example, silver powder may be used as the conductive powder. The conductive powder may have a nanometer or micrometer-scale particle size. For example, the conductive powder may have a particle size of dozens to several hundred nanometers, or a particle diameter of several to dozens of micrometers. In some implementations, the conductive powder may be a mixture of two or more types of conductive powders having different particle sizes.

The conductive powder may have a suitable particle shape such as a spherical, flake or amorphous particle shape.

The conductive powder may have an average particle diameter (D50) of about 0.1 μm to about 10 μm, or, for example, about 0.5 μm to about 5 μm. Within this range of average particle diameter, the conductive paste may reduce contact resistance and line resistance of a solar cell. The average particle diameter may be measured using, for example, a Model 1064D particle size analyzer (CILAS Co., Ltd.) after dispersing the conductive powder in isopropyl alcohol (IPA) at 25° C. for 3 minutes via ultrasonication.

The conductive powder may be present in an amount of about 60 wt % to about 95 wt % based on the total weight of the conductive paste. Within this range, the conductive paste may improve conversion efficiency of a solar cell and may be easily prepared in paste form. The conductive powder is present in an amount of, for example, about 70 wt % to about 90 wt % based on the total weight of the conductive paste. For example, the conductive powder may be present in an amount of about 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, 90 wt %, 91 wt %, 92 wt %, 93 wt %, 94 wt %, or 95 wt % based on the total weight of the conductive paste.

(2) Glass Frit

The glass frit may serve to form silver crystal grains in an emitter region by etching an anti-reflection layer and melting the conductive powder during a baking process of the electrode paste. The glass frit may improve adhesion of the conductive powder to a wafer and may soften to decrease the baking temperature during the baking process.

When sheet resistance of a solar cell is increased in order to improve solar cell efficiency, there is a possibility that contact resistance and current leakage may also increase in the solar cell. Thus, it is desirable to minimize both serial resistance (Rs) and influence on a p-n junction while maximizing open circuit voltage (Voc). In addition, the baking temperatures may vary within a broad range with increasing use of various wafers having different sheet resistances. Accordingly, it is desirable that the glass frit secure sufficient thermal stability to withstand a wide range of baking temperatures.

The glass frit may include, for example, tellurium and at least one of bismuth (Bi) and lead (Pb). For example, the glass frit may include at least one of a bismuth-tellurium-oxide (Bi—Te—O)-based glass frit, a lead-tellurium-oxide (Pb—Te—O)-based glass frit, and a lead-bismuth-tellurium-oxide (Pb—Bi—Te—O)-based glass frit.

In an embodiment, the glass frit may be a bismuth-tellurium-oxide (Bi—Te—O)-based glass fit. The glass frit may include about 1 mol % to about 30 mol % of bismuth (Bi) and about 30 mol % to about 60 mol % of tellurium (Te). A mole ratio of bismuth (Bi) to tellurium (Te) may range from about 1:0.1 to about 1:50.

In an embodiment, the glass fit may be a lead oxide-tellurium-oxide (Pb—Te—O)-based glass frit. The glass frit may include about 30 mol % to about 60 mol % of tellurium (Te), and a mole ratio of lead (Pb) to tellurium (Te) may range from about 1:0.1 to about 1:50.

In an embodiment, the glass frit may be a lead oxide-bismuth oxide-tellurium-oxide (Pb—Bi—Te—O)-based glass frit. The glass frit may include about 30 mol % to about 60 mol % of tellurium (Te). A mole ratio of the sum of lead (Pb) and bismuth (Bi) to tellurium (Te) may range from about 1:0.1 to about 1:50.

The glass fit may further include a metal and/or a metal oxide in addition to bismuth, lead, and tellurium. For example, the glass frit may further include at least one selected from lithium (Li), zinc (Zn), silver (Ag), phosphorus (P), germanium (Ge), gallium (Ga), cerium (Ce), iron (Fe), silicon (Si), tungsten (W), magnesium (Mg), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), and oxides thereof.

The glass fit may be prepared from such metal oxides by a suitable method known in the art. For example, the metal oxides may be mixed in a predetermined ratio. Mixing may be carried out using a ball mill or a planetary mill. The mixture may then be melted at about 900° C. to about 1,300° C., followed by quenching to 25° C. The obtained resultant may be subjected to pulverization using a disk mill, a planetary mill, or the like, thereby preparing a glass frit.

The glass frit may have an average particle diameter (D50) of about 0.1 μm to about 10 μm, and may have a spherical or amorphous shape.

The glass frit may be present in an amount of about 0.5 wt % to about 20 wt %, or, for example, about 0.5 wt % to about 3.5 wt %, based on the total weight of the conductive paste. Within this range, the glass frit may secure stability of a p-n junction under various sheet resistances, minimize serial resistance, and ultimately improve solar cell efficiency. For example, the glass frit may be present in an amount of about 0.5 wt %, 1 wt %, 1.5 wt %, 2 wt %, 2.5 wt %, 3 wt %, 3.5 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, or 20 wt % based on the total weight of the conductive paste.

(3) Organic Vehicle

The organic vehicle may impart suitable viscosity and rheological characteristics for printing to the conductive paste. The organic vehicle may be mechanically mixed with the inorganic component of the conductive paste.

The organic vehicle may be a suitable organic vehicle used in a conductive paste for solar cell electrodes. The organic vehicle may include a binder resin, a solvent, and the like.

The binder resin may be selected from acrylate resins or cellulose resins. For example, ethyl cellulose may be used as the binder resin. In addition, the binder resin may be selected from among ethyl hydroxyethyl cellulose, nitrocellulose, blends of ethyl cellulose and phenol resins, alkyd resins, phenol resins, acrylate ester resins, xylene resins, polybutane resins, polyester resins, urea resins, melamine resins, vinyl acetate resins, wood rosin, polymethacrylates of alcohols, or the like.

The solvent may be selected from, for example, hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, methylethylketone, benzyl alcohol, γ-butyrolactone, and ethyl lactate. These may be used alone or as a mixture thereof.

The organic vehicle may be present in an amount of, for example, about 1 wt % to about 30 wt % based on the total weight of the conductive paste. Within this range, the organic vehicle may provide sufficient adhesive strength and excellent printability to the conductive paste. For example, the organic vehicle may be present in an amount of about 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, or 30 wt % based on the total weight of the conductive paste.

(4) Additives

The conductive paste may further include additives to enhance fluidity and process properties and stability, as desired. The additives may include dispersants, thixotropic agents, plasticizers, viscosity stabilizers, anti-foaming agents, pigments, UV stabilizers, antioxidants, coupling agents, or the like. These additives may be used alone or as mixtures thereof. The additives may be present in an amount of about 0.1 wt % to about 5 wt % based on the total weight of the conductive paste. The content of the additives may be varied, as desired.

Printing the conductive paste may be performed through a procedure in which, after the printing mask having an opening rate of about 65% or more is disposed on the front surface of the substrate and the conductive paste is disposed on the printing mask, a pressing device such as a squeegee or a roller is moved on the conductive paste such that the conductive paste is printed onto the front surface of the substrate through openings of the printing mask.

Then, the conductive paste is subjected to drying at about 150° C. to about 400° C., or, for example, about 200° C. to about 400° C. The drying may be performed in an IR drying furnace. The drying may be performed, for example, for about 10 seconds to about 120 seconds.

Then, the printed conductive paste may be subjected to baking, thereby forming a finger electrode. The baking may be performed at about 600° C. to about 1,000° C. for about 10 seconds to about 120 seconds.

The finger electrode for a solar cell manufactured by the method as set forth above may be formed of a conductive paste including a conductive powder, a glass frit, and an organic vehicle and may exhibit a small height-dependent reduction in linewidth. Details of the conductive paste for the finger electrode are the same as those described above.

In the finger electrode, when the height of the finger electrode is H and the linewidth of a base of the finger electrode is A, a linewidth A′ of the finger electrode at a point of 0.5H satisfies Equation 1: 0.5A≤A′≤0.75A.

A′ may range from, for example, about 0.51A to about 0.65A. When A′, which represents the linewidth in the middle of the electrode, satisfies this range, a high short-circuit current and low series resistance can be obtained, thereby further improving conversion efficiency.

In addition, A, the linewidth of the base of the finger electrode, may range from about 30 μm to about 100 μm, or, for example, about 40 μm to about 80 μm, and H, the height of the finger electrode, may range from about 5 μm to about 25 μm, or, for example, about 10 μm to about 20 μm.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Preparative Example

Details of components used in the following Preparative Examples are as follows:

(A) Silver powder: Spherical silver powder having an average particle diameter of 2.0 μm (AG-5-11F, Dowa Hightech Co., Ltd.)

(B) Glass frit

(B1) Bi—Te—O-based glass frit having an average particle diameter of 2.0 μm and a glass transition temperature of 270° C. (ABT-1, Asahi Glass Co., Ltd.)

(B2) Pb—Te—O-based glass frit having an average particle diameter of 1.10 μm and a glass transition temperature of 240° C. (TDR-1, Asahi Glass Co., Ltd.)

(C) Organic binder: Ethylcellulose (STD4, Dow Chemical Company)

(D) Solvent: Texanol (Eastman Chemical Company)

(E) Resin component

(e1) An epoxy group-containing silicone resin (AY 42-119, Dow Corning Corporation)

(F) Dispersant: BYK-102 (BYK-Chemie)

(G) Thixotropic agent: Thixatrol ST (Elementis Co., Ltd.)

The aforementioned components were mixed with one another in amounts as listed in Table 1, thereby preparing a conductive paste. Specifically, (C) an organic binder was sufficiently dissolved in (D) a solvent at 60° C. to prepare an organic vehicle, and (A) silver powder, (B) a glass frit, (E) a dispersant, and (F) a thixotropic agent were added to the binder solution, followed by mixing and kneading in a 3-roll kneader, thereby preparing a conductive paste.

TABLE 1

| | | Preparative | Preparative | Preparative |
|---|---|---|---|---|
| Item (unit: wt %) | | Example 1 | Example 2 | Example 3 |
| (A) | | 89 | 89 | 89 |
| (B) | (B1) | 2.5 | — | 2.5 |
| | (B2) | — | 2.5 | — |

| | | | |
|---|---|---|---|
| (C) | 0.5 | 0.5 | 0.5 |
| (D) | 6.8 | 6.8 | 6.8 |
| (E) | 0.4 | 0.4 | 0.4 |
| (F) | 0.4 | 0.4 | 0.4 |
| (G) | 0.4 | 0.4 | 0.4 |

### Example 1

A printing mask having an opening rate of 82% and including an electrode printing portion having a linewidth of 26 μm (Sanli Precision Ind.) was placed on a semiconductor substrate. The conductive paste prepared in Preparative Example 1 was placed on the printing mask and then printed using a squeegee, followed by drying in an IR drying furnace. Then, an aluminum paste was printed on a back surface of the semiconductor substrate and dried in the same manner as above. Cells formed according to this procedure were subjected to baking at 950° C. for 45 seconds in a belt-type baking furnace, thereby fabricating a solar cell.

### Example 2

A solar cell was manufactured in the same manner as in Example 1 except that the conductive paste prepared in Preparative Example 2 was used.

### Example 3

A solar cell was manufactured in the same manner as in Example 1 except that the conductive paste prepared in Preparative Example 3 was used.

### Comparative Example 1

A solar cell was manufactured in the same manner as in Example 1 except that a printing mask having an opening rate of 63% and including an electrode printing portion having a linewidth of 37 μm (Lebon Screen Printing Equipment) was used.

After 3D profiles of the solar cell electrodes manufactured in Examples 1 to 3 and Comparative Example 1 were obtained using a three-dimensional measuring instrument (VK analyzer, KEYENCE Corporation), the average linewidth A at the base of the electrode, the height H of the electrode, and the average linewidth A′ at a point of 0.5H were measured using the 3D profiles, followed by calculation of A′/A. Results are shown in Table 2. In addition, each of the solar cells manufactured in in Examples 1 to 3 and Comparative Example 1 was evaluated as to short-circuit current (A), serial resistance (mΩ), and conversion efficiency (%) using a solar cell efficiency tester (CT-801, Pasan Co., Ltd.). Results are shown in Table 2.

TABLE 2

| | | | | | Short-circuit | | |
|---|---|---|---|---|---|---|---|
| | H | A′ | A | | current | Serial resistance | Conversion efficiency |
| Item | (μm) | (μm) | (μm) | A′/A | [A] | [mΩ] | [%] |
| Example 1 | 16.6 | 26.3 | 43.0 | 0.62 | 8.8972 | 3.85 | 19.18 |
| Example 2 | 15.4 | 28.6 | 40.2 | 0.71 | 8.8799 | 3.79 | 19.10 |
| Example 3 | 15.8 | 26.7 | 43.2 | 0.62 | 8.9123 | 3.84 | 19.08 |
| Comparative | 15.2 | 30.6 | 69.6 | 0.44 | 8.8582 | 3.72 | 19.01 |
| Example 1 | | | | | | | |

In Table 2, it may be seen that the solar cell electrodes of Examples 1 to 3, which were manufactured using the printing mask having an opening rate greater than 64% and had an average linewidth at a point of 0.5H satisfying the Equation 1: 0.5A≤A′≤0.75A could realize higher conversion efficiency than the solar cell electrode of Comparative Example 1, which was manufactured using the printing mask having an opening rate and an average linewidth at a point of 0.5H not satisfying the above ranges.

By way of summation and review, when a finger electrode is printed using a printing mask having a small opening rate as described above, since the electrode is formed in such a shape that the linewidth of the electrode is sharply decreased toward the upper side, there is a limit in improving the conversion efficiency of a solar cell.

Therefore, a finger electrode for a solar cell that exhibits a small height-dependent reduction in linewidth and thereby provides high conversion efficiency is desirable.

Embodiments provide a finger electrode for a solar cell which exhibits a small height-dependent reduction in linewidth, thereby providing high conversion efficiency

Embodiments provide a method of manufacturing the finger electrode for a solar cell that exhibits a small height-dependent reduction in linewidth.

Embodiments provide a finger electrode for a solar cell that exhibits a small height-dependent reduction in linewidth and thus has a large total area, thereby realizing high conversion efficiency.

Embodiments provide a finger electrode for a solar cell that has a larger area than general finger electrodes, thereby realizing excellent conversion efficiency, and a method of manufacturing the same.

Embodiments provide a method of manufacturing a finger electrode for a solar cell that uses a printing mask having a high opening rate, whereby a finger electrode exhibiting a small height-dependent reduction in linewidth can be formed.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope thereof as set forth in the following claims.

What is claimed is:

1. A finger electrode for a solar cell formed using a conductive paste comprising a conductive powder, a glass frit, and an organic vehicle,
wherein a linewidth A′ of the finger electrode at a point 0.5H satisfies the following Equation 1: 0.5A≤A′≤0.75A
where H is the height of the finger electrode and A is the linewidth of a base of the finger electrode.

2. The finger electrode for a solar cell as claimed in claim 1, wherein the linewidth A of the base of the finger electrode ranges from about 30 μm to about 100 μm.

3. The finger electrode for a solar cell as claimed in claim 1, wherein the height H of the finger electrode ranges from about 10 μm to about 20 μm.

4. The finger electrode for a solar cell as claimed in claim 1, wherein the conductive paste includes about 60 wt % to about 95 wt % of the conductive powder, about 0.5 wt % to about 20 wt % of the glass frit, and about 1 wt % to about 30 wt % of the organic vehicle.

5. The finger electrode for a solar cell as claimed in claim 1, wherein the glass frit includes at least one of a bismuth-tellurium-oxide (Bi—Te—O)-based glass frit, a lead-tellurium-oxide (Pb—Te—O)-based glass frit, and a lead-bismuth-tellurium-oxide (Pb—Bi—Te—O)-based glass frit.

6. The finger electrode for a solar cell as claimed in claim 1, wherein the conductive paste further includes at least one additive selected from a dispersant, a thixotropic agent, a plasticizer, a viscosity stabilizer, an anti-foaming agent, a pigment, a UV stabilizer, an antioxidant, and a coupling agent.

7. A method of manufacturing a finger electrode for a solar cell, the method comprising:
(a) printing a conductive paste on a front surface of a substrate using a printing mask having an opening rate of about 65% or more; and
(b) baking the printed conductive paste.

8. The method as claimed in claim 7, wherein the printing mask has an opening rate of about 65% to about 90%.

9. The method as claimed in claim 7, wherein the printing mask includes a mesh, a photosensitive resin layer integrated with the mesh, and an electrode printing portion formed by removing the photosensitive resin layer.

10. The method as claimed in claim 9, wherein:
the mesh includes weft threads, and
a distance between weft threads of the mesh above and below the electrode printing portion is longer than the distance between weft threads of the mesh in other regions of the printing mask.

11. The method as claimed in claim 7, wherein baking of the conductive paste is performed at about 600° C. to about 1,000° C.
